(19) United States
(12) Patent Application Publication
(10) Pub. No.: US 2019/0287938 A1
(43) Pub. Date: Sep. 19, 2019

(54) FAN-OUT COMPONENT PACKAGE

(71) Applicant: SAMSUNG ELECTRONICS CO., LTD., Suwon-si (KR)

(72) Inventors: Jong Rok KIM, Suwon-Si (KR); Min Keun KIM, Suwon-Si (KR); Yong Ho BAEK, Suwon-Si (KR); Young Sik HUR, Suwon-Si (KR); Jung Chul GONG, Suwon-Si (KR)

(73) Assignee: SAMSUNG ELECTRONICS CO., LTD., Suwon-si (KR)

(21) Appl. No.: 16/119,913

(22) Filed: Aug. 31, 2018

(30) Foreign Application Priority Data
Mar. 13, 2018 (KR) 10-2018-0029384

(51) Int. Cl. H01L 23/00; H01L 23/552

(52) U.S. Cl. CPC H01L 24/25; H01L 24/24; H01L 23/552; H01L 2224/25171; H01L 2224/24265; H01L 2224/24155; H01L 2224/24195

(57) ABSTRACT

A fan-out component package includes: a core member having a through-hole and including wiring layers and one or more connection vias; one or more first electronic components disposed in the through-hole; a first encapsulant covering at least portions of the core member and the first electronic components and filling at least a portion of the through-hole; a connection member disposed on the core member and the first electronic components and including one or more redistribution layers electrically connected to the wiring layers and the first electronic components; one or more second electronic components disposed on the connection member and electrically connected to the redistribution layers; and a second encapsulant disposed on the connection member and encapsulating the second electronic components, wherein an upper surface of the connection member and a lower surface of the second encapsulant are spaced apart from each other by a predetermined interval.

### CROSS-REFERENCE TO RELATED APPLICATION(S)

This application claims the benefit of priority to Korean Patent Application No. 10-2018-0029384 filed on Mar. 13, 2018, in the Korean Intellectual Property Office, the disclosure of which is incorporated herein by reference in its entirety.

### TECHNICAL FIELD

The present disclosure relates to a fan-out component package in which a semiconductor chip or a passive component is packaged in a fan-out form.

### BACKGROUND

Recently, in accordance with the trend for multifunctionalization (facial recognition, three-dimensional (3D) cameras, and the like) of smartphones, an increase in sizes of displays of the smartphones, the use of full panel displays in the smartphones, and the like, the necessity of increasing the capacity of batteries has increased. As a result, the sizes of main boards in smartphones have been reduced. Therefore, various methods for securing a mounting area have been demanded.

### SUMMARY

An aspect of the present disclosure may provide a fan-out component package of which a mounting density may be increased in a main board in an electronic device.

According to an aspect of the present disclosure, a fan-out component package maybe provided, in which a plurality of components are packaged in fan-out form in a double-sided mounting manner.

According to an aspect of the present disclosure, a fan-out component package may include: a core member having a through-hole and including a plurality of wiring layers and one or more connection vias electrically connecting the plurality of wiring layers to each other; one or more first electronic components disposed in the through-hole; a first encapsulant covering at least portions of each of the core member and the first electronic components and filling at least a portion of the through-hole; a connection member disposed on the core member and the first electronic components and including one or more redistribution layers electrically connected to the wiring layers and the first electronic components; one or more second electronic components disposed on the connection member and electrically connected to the redistribution layers; and a second encapsulant disposed on the connection member and encapsulating the second electronic components, wherein an upper surface of the connection member and a lower surface of the second encapsulant are spaced apart from each other by a predetermined interval.

According to another aspect of the present disclosure, a fan-out component package may include: a core member having a through-hole and including a plurality of wiring layers and one or more connection vias electrically connecting the plurality of wiring layers to each other; a semiconductor chip disposed in the through-hole and having an active surface having connection pads disposed thereon and an inactive surface opposing the active surface; a first encapsulant covering at least portions of each of the core member and the inactive surface of the semiconductor chip and filling at least a portion of the through-hole; a connection member disposed on the core member and the active surface of the semiconductor chip and including one or more redistribution layers electrically connected to the wiring layers and the connection pads; a plurality of passive components disposed on the connection member and electrically connected to the redistribution layers; and a second encapsulant disposed on the connection member and encapsulating the plurality of passive components, wherein at least one of the plurality of passive components is disposed in the active surface of the semiconductor chip when viewed in a direction perpendicular to the active surface of the semiconductor chip.

### BRIEF DESCRIPTION OF DRAWINGS

The above and other aspects, features, and advantages of the present disclosure will be more clearly understood from the following detailed description taken in conjunction with the accompanying drawings, in which:

FIG. 1 is a schematic block diagram illustrating an example of an electronic device system;

FIG. 2 is a schematic perspective view illustrating an example of an electronic device;

FIGS. 3A and 3B are schematic cross-sectional views illustrating states of a fan-in semiconductor package before and after being packaged;

FIG. 4 is schematic cross-sectional views illustrating a packaging process of a fan-in semiconductor package;

FIG. 5 is a schematic cross-sectional view illustrating a case in which a fan-in semiconductor package is mounted on a ball grid array (BGA) substrate and is ultimately mounted on a mainboard of an electronic device;

FIG. 6 is a schematic cross-sectional view illustrating a case in which a fan-in semiconductor package is embedded in a BGA substrate and is ultimately mounted on a mainboard of an electronic device;

FIG. 7 is a schematic cross-sectional view illustrating a fan-out semiconductor package;

FIG. 8 is a schematic cross-sectional view illustrating a case in which a fan-out semiconductor package is mounted on a mainboard of an electronic device;

FIG. 9 is a schematic cross-sectional view illustrating an example of a fan-out component package;

FIG. 10 is a schematic plan view taken along line I-I′ of the fan-out component package of FIG. 9;

FIGS. 11 and 12 are schematic views illustrating processes of manufacturing the fan-out component package of FIG. 9;

FIG. 13 is a schematic cross-sectional view illustrating another example of a fan-out component package;

FIG. 14 is a schematic cross-sectional view illustrating another example of a fan-out component package;

FIG. 15 is a schematic cross-sectional view illustrating another example of a fan-out component package;

FIG. 16 is a schematic cross-sectional view illustrating another example of a fan-out component package;

FIG. 17 is a schematic cross-sectional view illustrating another example of a fan-out component package; and

FIG. 18 is schematic plan views illustrating one effect in a case in which a fan-out component package according to the present disclosure is used on a main board of an electronic device.

### DETAILED DESCRIPTION

Hereinafter, exemplary embodiments in the present disclosure will be described with reference to the accompanying drawings. In the accompanying drawings, shapes, sizes, and the like, of components may be exaggerated or shortened for clarity.

Herein, a lower side, a lower portion, a lower surface, and the like, are used to refer to a direction toward a mounting surface of the fan-out component package in relation to cross sections of the drawings, while an upper side, an upper portion, an upper surface, and the like, are used to refer to an opposite direction to the direction. However, these directions are defined for convenience of explanation, and the claims are not particularly limited by the directions defined as described above.

The meaning of a “connection” of a component to another component in the description includes an indirect connection through an adhesive layer as well as a direct connection between two components. In addition, “electrically connected” conceptually includes a physical connection and a physical disconnection. It can be understood that when an element is referred to with terms such as “first” and “second”, the element is not limited thereby. They may be used only for a purpose of distinguishing the element from the other elements, and may not limit the sequence or importance of the elements. In some cases, a first element may be referred to as a second element without departing from the scope of the claims set forth herein. Similarly, a second element may also be referred to as a first element.

The term “an exemplary embodiment” used herein does not refer to the same exemplary embodiment, and is provided to emphasize a particular feature or characteristic different from that of another exemplary embodiment. However, exemplary embodiments provided herein are considered to be able to be implemented by being combined in whole or in part one with one another. For example, one element described in a particular exemplary embodiment, even if it is not described in another exemplary embodiment, may be understood as a description related to another exemplary embodiment, unless an opposite or contradictory description is provided therein.

Terms used herein are used only in order to describe an exemplary embodiment rather than limiting the present disclosure. In this case, singular forms include plural forms unless interpreted otherwise in context.

### Electronic Device

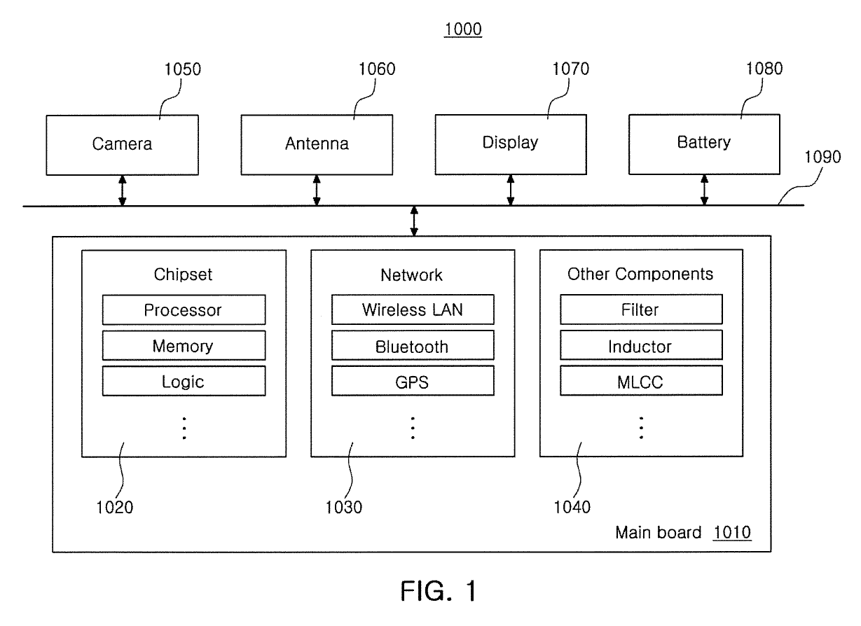

FIG. 1 is a schematic block diagram illustrating an example of an electronic device system.

Referring to FIG. 1, an electronic device 1000 may accommodate a mainboard 1010 therein. The mainboard 1010 may include chip related components 1020, network related components 1030, other components 1040, and the like, physically or electrically connected thereto. These components may be connected to others to be described below to form various signal lines 1090.

The chip related components 1020 may include a memory chip such as a volatile memory (for example, a dynamic random access memory (DRAM)), a non-volatile memory (for example, a read only memory (ROM)), a flash memory, or the like; an application processor chip such as a central processor (for example, a central processing unit (CPU)), a graphics processor (for example, a graphics processing unit (GPU)), a digital signal processor, a cryptographic processor, a microprocessor, a microcontroller, or the like; and a logic chip such as an analog-to-digital (ADC) converter, an application-specific integrated circuit (ASIC), or the like. However, the chip related components 1020 are not limited thereto, but may also include other types of chip related components. In addition, the chip related components 1020 may be combined with each other.

The network related components 1030 may include protocols such as wireless fidelity (Wi-Fi) (Institute of Electrical And Electronics Engineers (IEEE) 802.11 family, or the like), worldwide interoperability for microwave access (WiMAX) (IEEE 802.16 family, or the like), IEEE 802.20, long term evolution (LTE), evolution data only (Ev-DO), high speed packet access+(HSPA+), high speed downlink packet access+(HSDPA+), high speed uplink packet access+(HSUPA+), enhanced data GSM environment (EDGE), global system for mobile communications (GSM), global positioning system (GPS), general packet radio service (GPRS), code division multiple access (CDMA), time division multiple access (TDMA), digital enhanced cordless telecommunications (DECT), Bluetooth, 3G, 4G, and 5G protocols, and any other wireless and wired protocols, designated after the abovementioned protocols. However, the network related components 1030 are not limited thereto, but may also include a variety of other wireless or wired standards or protocols. In addition, the network related components 1030 may be combined with each other, together with the chip related components 1020 described above.

Other components 1040 may include a high frequency inductor, a ferrite inductor, a power inductor, ferrite beads, a low temperature co-fired ceramic (LTCC), an electromagnetic interference (EMI) filter, a multilayer ceramic capacitor (MLCC), or the like. However, other components 1040 are not limited thereto, but may also include passive components used for various other purposes, or the like. In addition, other components 1040 may be combined with each other, together with the chip related components 1020 or the network related components 1030 described above.

Depending on a type of the electronic device 1000, the electronic device 1000 may include other components that may or may not be physically or electrically connected to the mainboard 1010. These other components may include, for example, a camera module 1050, an antenna 1060, a display device 1070, a battery 1080, an audio codec (not illustrated), a video codec (not illustrated), a power amplifier (not illustrated), a compass (not illustrated), an accelerometer (not illustrated), a gyroscope (not illustrated), a speaker (not illustrated), a mass storage unit (for example, a hard disk drive) (not illustrated), a compact disk (CD) drive (not illustrated), a digital versatile disk (DVD) drive (not illustrated), or the like. However, these other components are not limited thereto, but may also include other components used for various purposes depending on a type of electronic device 1000, or the like.

The electronic device 1000 may be a smartphone, a personal digital assistant (PDA), a digital video camera, a digital still camera, a network system, a computer, a monitor, a tablet PC, a laptop PC, a netbook PC, a television, a video game machine, a smartwatch, an automotive component, or the like. However, the electronic device 1000 is not limited thereto, but may be any other electronic device processing data.

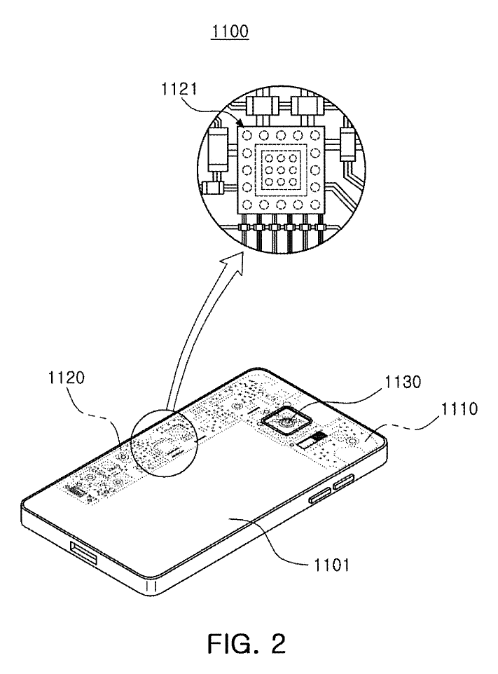

FIG. 2 is a schematic perspective view illustrating an example of an electronic device.

Referring to FIG. 2, a semiconductor package may be used for various purposes in the various electronic devices 1000 as described above. For example, a mainboard 1110 may be accommodated in a body 1101 of a smartphone 1100, and various electronic components 1120 may be physically or electrically connected to the mainboard 1110. In addition, other components that may or may not be physically or electrically connected to the mainboard 1110, such as a camera module 1130, may be accommodated in the body 1101. Some of the electronic components 1120 may be the chip related components, for example, a semiconductor package 1121, but are not limited thereto. The electronic device is not necessarily limited to the smartphone 1100, but may be other electronic devices as described above.

### Semiconductor Package

Generally, numerous fine electrical circuits are integrated in a semiconductor chip. However, the semiconductor chip may not serve as a finished semiconductor product in itself, and may be damaged due to external physical or chemical impacts. Therefore, the semiconductor chip itself may not be used, but may be packaged and used in an electronic device, or the like, in a packaged state.

Here, semiconductor packaging is required due to the existence of a difference in a circuit width between the semiconductor chip and a mainboard of the electronic device in terms of electrical connections. In detail, a size of connection pads of the semiconductor chip and an interval between the connection pads of the semiconductor chip are very fine, but a size of component mounting pads of the mainboard used in the electronic device and an interval between the component mounting pads of the mainboard are significantly larger than those of the semiconductor chip. Therefore, it may be difficult to directly mount the semiconductor chip on the mainboard, and packaging technology for buffering a difference in a circuit width between the semiconductor chip and the mainboard is required.

A semiconductor package manufactured by the packaging technology may be classified as a fan-in semiconductor package or a fan-out semiconductor package depending on a structure and a purpose thereof.

The fan-in semiconductor package and the fan-out semiconductor package will hereinafter be described in more detail with reference to the drawings.

### Fan-In Semiconductor Package

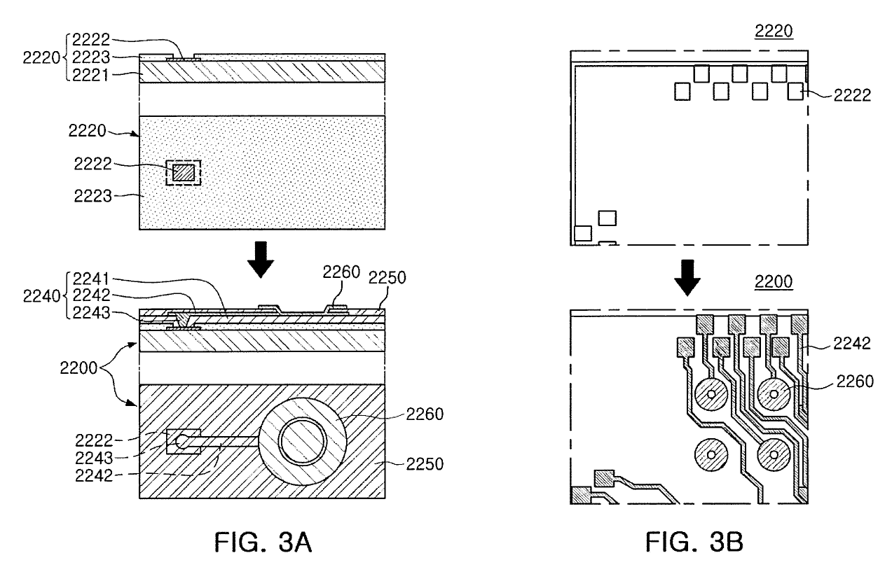

FIGS. 3A and 3B are schematic cross-sectional views illustrating states of a fan-in semiconductor package before and after being packaged.

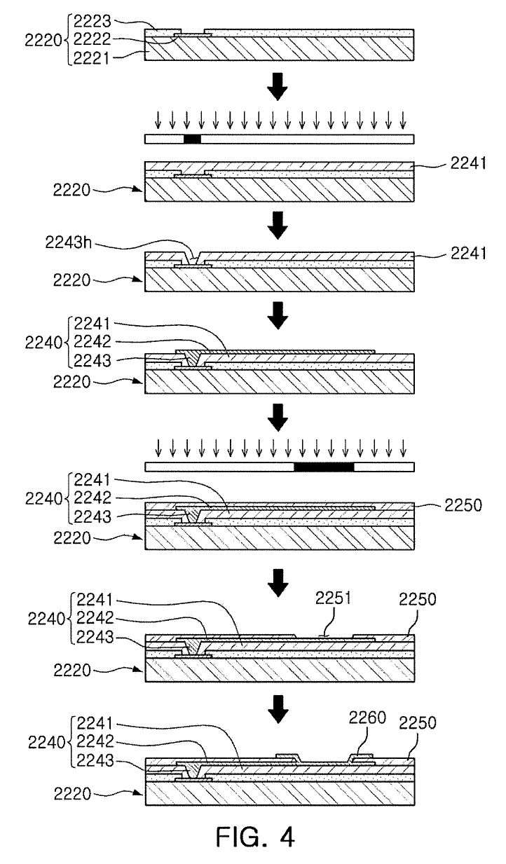

FIG. 4 is schematic cross-sectional views illustrating a packaging process of a fan-in semiconductor package.

Referring to FIGS. 3 and 4, a semiconductor chip 2220 may be, for example, an integrated circuit (IC) in a bare state, including a body 2221 including silicon (Si), germanium (Ge), gallium arsenide (GaAs), or the like, connection pads 2222 formed on one surface of the body 2221 and including a conductive material such as aluminum (Al), or the like, and a passivation layer 2223 such as an oxide layer, a nitride layer, or the like, formed on one surface of the body 2221 and covering at least portions of the connection pads 2222. In this case, since the connection pads 2222 may be significantly small, it may be difficult to mount the integrated circuit (IC) on an intermediate level printed circuit board (PCB) as well as on the mainboard of the electronic device, or the like.

Therefore, a connection member 2240 may be formed depending on a size of the semiconductor chip 2220 on the semiconductor chip 2220 in order to redistribute the connection pads 2222. The connection member 2240 may be formed by forming an insulating layer 2241 on the semiconductor chip 2220 using an insulating material such as a photoimagable dielectric (PID) resin, forming connection via holes 2243h opening the connection pads 2222, and then forming wiring patterns 2242 and connection vias 2243. Then, a passivation layer 2250 protecting the connection member 2240 may be formed, an opening 2251 may be formed, and an underbump metal layer 2260, or the like, may be formed. That is, a fan-in semiconductor package 2200 including, for example, the semiconductor chip 2220, the connection member 2240, the passivation layer 2250, and the underbump metal layer 2260 may be manufactured through a series of processes.

As described above, the fan-in semiconductor package may have a package form in which all of the connection pads, for example, input/output (I/O) terminals, of the semiconductor chip are disposed inside the semiconductor chip, and may have excellent electrical characteristics and be produced at a low cost. Therefore, many elements mounted in smartphones have been manufactured in a fan-in semiconductor package form. In detail, many elements mounted in smartphones have been developed to implement a rapid signal transfer while having a compact size.

However, since all I/O terminals need to be disposed inside the semiconductor chip in the fan-in semiconductor package, the fan-in semiconductor package has significant spatial limitations. Therefore, it is difficult to apply this structure to a semiconductor chip having a large number of I/O terminals or a semiconductor chip having a compact size. In addition, due to the disadvantage described above, the fan-in semiconductor package may not be directly mounted and used on the mainboard of the electronic device. The reason is that even in a case in which a size of the I/O terminals of the semiconductor chip and an interval between the I/O terminals of the semiconductor chip are increased by a redistribution process, the size of the I/O terminals of the semiconductor chip and the interval between the I/O terminals of the semiconductor chip may not be sufficient to directly mount the fan-in electronic component package on the mainboard of the electronic device.

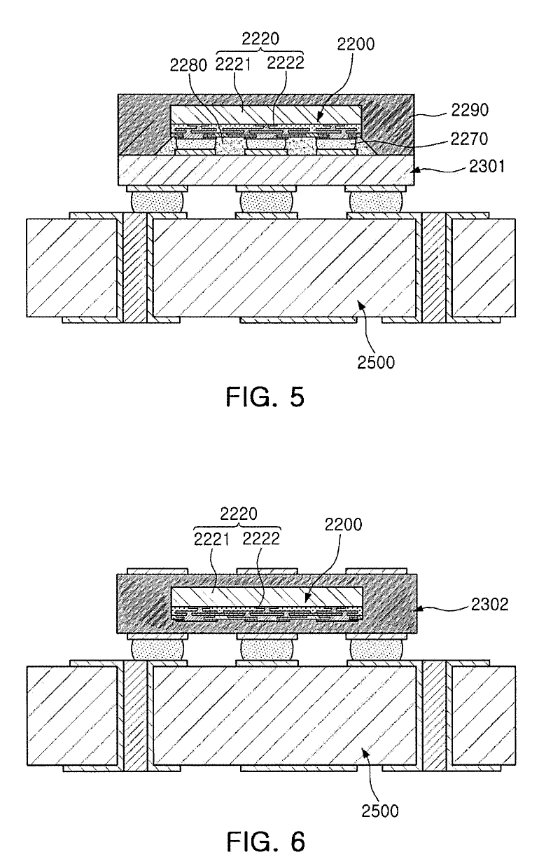

FIG. 5 is a schematic cross-sectional view illustrating a case in which a fan-in semiconductor package is mounted on a ball grid array (BGA) substrate and is ultimately mounted on a mainboard of an electronic device.

FIG. 6 is a schematic cross-sectional view illustrating a case in which a fan-in semiconductor package is embedded in a BGA substrate and is ultimately mounted on a mainboard of an electronic device.

Referring to FIGS. 5 and 6, in a fan-in semiconductor package 2200, connection pads 2222, that is, I/O terminals, of a semiconductor chip 2220 may be redistributed through a BGA substrate 2301, and the fan-in semiconductor package 2200 may be ultimately mounted on a mainboard 2500 of an electronic device in a state in which it is mounted on the BGA substrate 2301. In this case, solder balls 2270, and the like, maybe fixed by an underfill resin 2280, or the like, and an outer side of the semiconductor chip 2220 may be covered with a molding material 2290, or the like. Alternatively, a fan-in semiconductor package 2200 may be embedded in a separate BGA substrate 2302, connection pads 2222, that is, I/O terminals, of the semiconductor chip 2220 may be redistributed by the BGA substrate 2302 in a state in which the fan-in semiconductor package 2200 is embedded in the BGA substrate 2302, and the fan-in semiconductor package 2200 may be ultimately mounted on a mainboard 2500 of an electronic device.

As described above, it may be difficult to directly mount and use the fan-in semiconductor package on the mainboard of the electronic device. Therefore, the fan-in semiconductor package may be mounted on the separate BGA substrate and be then mounted on the mainboard of the electronic device through a packaging process or may be mounted and used on the mainboard of the electronic device in a state in which it is embedded in the BGA substrate.

### Fan-Out Semiconductor Package

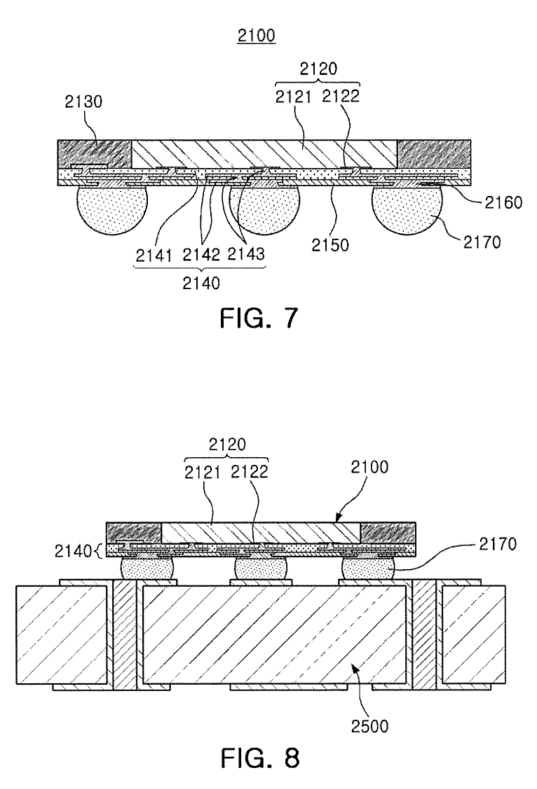

FIG. 7 is a schematic cross-sectional view illustrating a fan-out semiconductor package.

Referring to FIG. 7, in a fan-out semiconductor package 2100, for example, an outer side of a semiconductor chip 2120 may be protected by an encapsulant 2130, and connection pads 2122 of the semiconductor chip 2120 may be redistributed outwardly of the semiconductor chip 2120 by a connection member 2140. In this case, a passivation layer 2150 may further be formed on the connection member 2140, and an underbump metal layer 2160 may further be formed in openings of the passivation layer 2150. Solder balls 2170 may further be formed on the underbump metal layer 2160. The semiconductor chip 2120 may be an integrated circuit (IC) including a body 2121, the connection pads 2122, a passivation layer (not illustrated) , and the like.

The connection member 2140 may include an insulating layer 2141, redistribution layers 2142 formed on the insulating layer 2141, and connection vias 2143 electrically connecting the connection pads 2122 and the redistribution layers 2142 to each other.

As described above, the fan-out semiconductor package may have a form in which I/O terminals of the semiconductor chip are redistributed and disposed outwardly of the semiconductor chip through the connection member formed on the semiconductor chip. As described above, in the fan-in semiconductor package, all I/O terminals of the semiconductor chip need to be disposed inside the semiconductor chip. Therefore, when a size of the semiconductor chip is decreased, a size and a pitch of balls need to be decreased, such that a standardized ball layout may not be used in the fan-in semiconductor package. On the other hand, the fan-out semiconductor package has the form in which the I/O terminals of the semiconductor chip are redistributed and disposed outwardly of the semiconductor chip through the connection member formed on the semiconductor chip as described above. Therefore, even in a case in which a size of the semiconductor chip is decreased, a standardized ball layout may be used in the fan-out semiconductor package as it is, such that the fan-out semiconductor package may be mounted on the mainboard of the electronic device without using a separate BGA substrate, as described below.

FIG. 8 is a schematic cross-sectional view illustrating a case in which a fan-out semiconductor package is mounted on a mainboard of an electronic device.

Referring to FIG. 8, a fan-out semiconductor package 2100 may be mounted on a mainboard 2500 of an electronic device through solder balls 2170, or the like. That is, as described above, the fan-out semiconductor [symbol] 2100 includes connection member 2140 formed on the [symbol] emiconductor chip 2 [symbol] and capable of redistributing the co [symbol] nection pads 2122 t [symbol] fan-out region that is outside of a s [symbol] ze of the semiconduct [symbol] chip 2120, such that the standardized [symbol] ball layout may be us [symbol] in the fan-out semiconductor package 2 [symbol] 00 as it is. As a resul [symbol] the fan-out semiconductor package 21 [symbol] may be mounted on t [symbol] mainboard 2500 of the electronic device [symbol] ithout using a separat [symbol] BGA substrate, or the like.

As described above, since th [symbol] fan-out semiconducto [symbol] package may be mounted on the mainboard [symbol] f the electronic devic [symbol] without using the separate BGA s [symbol] strate, the fan-out semiconductor package may be implemen [symbol] d at a thickness lower than that of the fan-in semiconducto [symbol] package using the BGA substrate. Therefore, the fan-out semi [symbol] nductor package may be miniaturized and thinned. In addition, [symbol] he fan-out electronic component package has excellent ther [symbol] characteristics and electrical characteristics, such th [symbol] it is partcularly appropriate for a mobile product. [symbol] refore, the fan-out electronic component package may be im [symbol] mented in a form more compact than that of a general packag [symbol] n-package (POP) type using a printed circuit board (PCB), [symbol] may solve a problem due to the occurrernce of a warpage p [symbol] omenon.

Meanwhile, the fan-out semicon [symbol] tor package refers to package technology for mounting the s [symbol] ondcutor chip on the mainboard of the electronic device, or the like, as described above, and protecting the semiconductor chip from external impacts, and is a concept different from that of a printed circuit board (PCB) such as a BGA substrate, or the like, having a scale, a purpose, and the like, different from those of the fan-out semiconductor package, and having the fan-in semiconductor package embedded therein.

A fan-out component package of which a mounting density may be increased in a mainboard in an electronic device, a thickness may be significantly decreased in spite of the increase in the mounting density, and electrical characteristics may be improved due to a reduction in a signal distance will hereinafter be described with reference to the drawings.

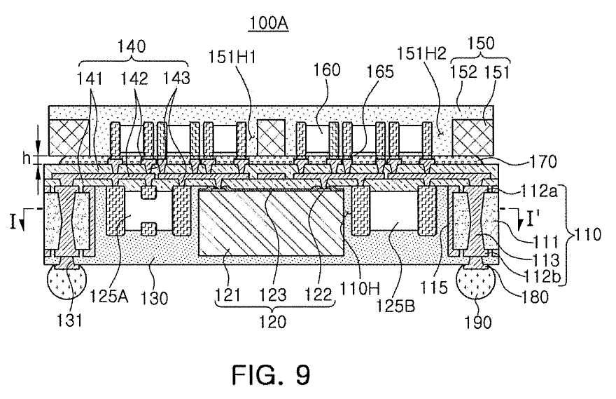

FIG. 9 is a schematic cross-sectional view illustrating an example of a fan-out component package.

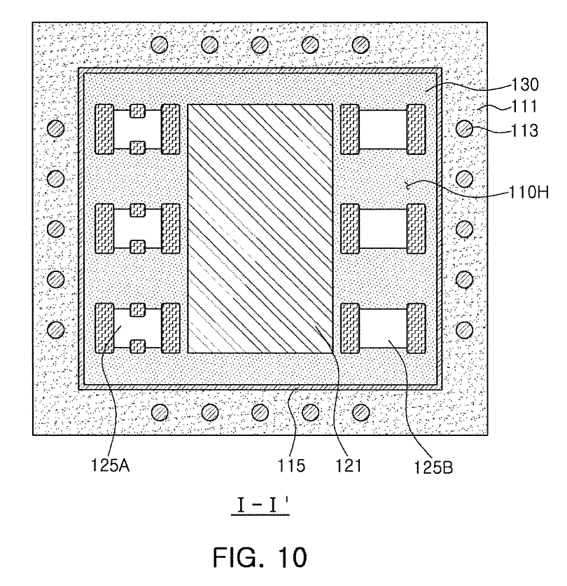

FIG. 10 is a schematic plan view taken along line I-I′ of the fan-out component package of FIG. 9.

Referring to FIGS. 9 and 10, a fan-out component package 100A according to an exemplary embodiment in the present disclosure may include a core member 110 having a through-hole 110H and including first and second wiring layers 112a and 112b and connection vias 113 electrically connecting the first and second wiring layers 112a and 112b to each other, a semiconductor chip 120 disposed in the through-hole 110H and having an active surface having connection pads 122 disposed thereon and an inactive surface opposing the active surface, a first encapsulant 130 covering at least portions of the core member 110 and the semiconductor chip 120 and filling at least a portion of the through-hole 110H, a connection member 140 disposed on the core member 110 and the active surface of the semiconductor chip 120 and including redistribution layers 142 electrically connected to the first and second wiring layers 112a and 112b and the connection pads 122, one or more electronic components 160 disposed on the connection member 140 and electrically connected to the redistribution layers 142, and a second encapsulant 150 disposed on the connection member 140 and encapsulating the electronic components 160. In this case, an upper surface of the connection member 140 and a lower surface of the second encapsulant 150 may be spaced apart from each other by a predetermined interval h. The electronic components 160 may be electrically connected to the redistribution layers 142 of the connection member 140 through low melting point metals 165. A space between the upper surface of the connection member 140 and the lower surface of the second encapsulant 150 may be filled with an underfill resin 170 burying the low melting point metals 165. One or more passive components 125A and 125B may be disposed, in addition to the semiconductor chip 120, in the through-hole 110H, and may be encapsulated through the first encapsulant 130. The passive components 125A and 125B may also be electrically connected to the redistribution layers 142 of the connection member 140, and may be electrically connected to the connection pads 122 of the semiconductor chip 120 or the electronic components 160 through the redistribution layers 142. A plurality of openings 131 exposing at least portions of the second wiring layer 112b of the core member 110 may be formed in a lower surface of the first encapsulant 130, a plurality of underbump metals 180 may be disposed in the openings 131, respectively, and a plurality of electronic connection structures 190 disposed beneath the first encapsulant 130 may be electrically connected to the exposed second wiring layer 112b through the plurality of underbump metals 180, respectively. The semiconductor chip 120, the passive components 125A and 125B, and/or the electronic components 160 may be electrically connected to a mainboard of an electronic device through the electrical connection structures 190 depending on functions, by a series of electrical connections.

Recently, in accordance with an increase in sizes of displays for mobile apparatuses, the necessity to increase capacity of batteries has increased. In accordance with the increase in the capacity of the batteries, areas occupied by the batteries in the mobile apparatuses have increased, and it has thus been required to reduce a size of a printed circuit board (PCB) such as a mainboard. Therefore, amounting area of components has reduced, such that interest in modularization has continuously increased. An example of the related art of mounting a plurality of components may include chip on board (COB) technology. The COB is a method of mounting individual passive elements and a semiconductor package on a printed circuit board using surface mount technology (SMT). Such a manner has an advantage in terms of cost, but a wide mounting area is required in order to maintain a minimum interval between components, electromagnetic interference (EMI) between the components is large, and a distance between the semiconductor chip and the passive components is great, such that electrical noise is increased.

On the other hand, in the fan-out component package 100A according to the exemplary embodiment, one or more electronic components 160 and one or more passive components 125A and 125B maybe disposed and modularized together with the semiconductor chip 120 in a double-sided mounting form in one package. Therefore, a spacing between the components may be significantly reduced, and a mounted area of the components on a printed circuit board such as a main board, or the like, may thus be significantly reduced. In addition, electrical paths between the semiconductor chip 120 and the electronic components 160 and/or the passive components 125A and 125B may be significantly reduced to suppress noise. Particularly, the semiconductor chip 120, the passive components 125A and 125B, and the electronic components 160 may be disposed in a double-sided mounting form with respect to the connection member 140, and the fan-out component package may thus be thinned.

Meanwhile, in the fan-out component package 100A according to the exemplary embodiment, the core member 110 capable of maintaining rigidity of the fan-out component package may be introduced, and the semiconductor chip 120 and/or the passive components 125A and 125B may be disposed in the through-hole 110H of the core member 110, and the warpage of the fan-out component package may thus be suppressed. In addition, the second encapsulant 150 encapsulating the electronic components 160 may include a core layer 151 having cavities 151H1 and 151H2 and a resin layer 152 encapsulating the core layer 151 and the electronic components 160 depending on a manufacturing process, and the core layer 151 maybe formed of a material having rigidity greater than that of the resin layer 152, for example, an elastic modulus greater than that of the resin layer 152. Waipage of an upper unit of the fan-out component package may thus be also suppressed. In addition, a metal layer 115 may be disposed on walls of the through-hole 110H of the core member 110, if necessary, and a heat dissipation effect and an electromagnetic interference blocking effect may be achieved through the metal layer 115. Meanwhile, the electronic components 160 may be a plurality of passive components 160. In this case, the passive components 125A and 125B disposed together with the semiconductor chip 120 in the through-hole 110H of the core member 110 may have a thickness relatively greater than that of the plurality of passive components 160 mounted on the connection member 140. That is, the passive components 125A and 125B having a relatively large thickness may be disposed at a lower portion of the fan-out component package and the passive components 160 having a relatively small thickness may be disposed at an upper portion of the fan-out component package, such that an overall thickness of the fan-out component package may be reduced, and a component mounting defect such as a filling defect or a fly that may occur in an encapsulating process may be suppressed.

The respective components included in the fan-out component package 100A according to the exemplary embodiment will hereinafter be described below in more detail.

The core member 110 may maintain rigidity of the fan-out component package 100A according to the exemplary embodiment depending on certain materials, and serve to secure uniformity of a thickness of the first encapsulant 130. In addition, the core member 110 may provide a vertical electrical connection path in the fan-out component package, and the connection pads 122 of the semiconductor chip 120 or the passive components 125A and 1253 may thus be electrically connected to the electrical connection structures 190 disposed at a lower portion of the fan-out component package. In addition, the core member 110 may include a plurality of wiring layers 112a and 112b to more effectively redistribute the connection pads 122 of the semiconductor chip 120, and may provide a wide wiring design region to suppress redistribution layers from being formed in other regions. The semiconductor chip 120 and/or the passive components 125A and 125B may be disposed in the through-hole 110H to be spaced apart from the walls of the through-hole 110H by a predetermined distance. If necessary, the metal layer 115 may be disposed on the walls of the through-hole 110H to achieve the electromagnetic interference blocking effect and the heat dissipation effect. The core member 110 may include an insulating layer 111, the first wiring layer 112a disposed on an upper surface of the insulating layer 111, the second wiring layer 112b disposed on a lower surface of the insulating layer 111, and connection vias 113 penetrating through the insulating layer 111 and electrically connecting the first and second wiring layers 112a and 112b to each other.

For example, a material including an inorganic filler and an insulating resin may be used as a material of the insulating layer 111. For example, a thermosetting resin such as an epoxy resin, a thermoplastic resin such as a polyimide resin, or a resin including a reinforcing material such as an inorganic filler, for example, silica, alumina, or the like, more specifically, an Ajinomoto Build up Film (ABF), FR-4, Bismaleimide Triazine (BT), a photoimagable dielectric (PID) resin, or the like, may be used. Alternatively, a material in which a thermosetting resin or a thermoplastic resin is impregnated together with an inorganic filler in a core material such as a glass fiber (or a glass cloth or a glass fabric), for example, prepreg, or the like, may be used. In this case, excellent rigidity of the fan-out component package 100A may be maintained, such that the core member 110 may be used as a kind of support member.

The wiring layers 112a and 112b may include a conductive material such as copper (Cu), aluminum (Al), silver (Ag), tin (Sn), gold (Au), nickel (Ni), lead (Pb), titanium (Ti), or alloys thereof. The respective wiring layers 112a and 112b may perform various functions depending on designs of corresponding layers. For example, the wiring layers 112a and 112b may include ground (GND) patterns, power (PWR) patterns, signal (S) patterns, and the like. Here, the signal (S) patterns may include various signals except for the ground (GND) patterns, the power (PWR) patterns, and the like, such as data signals, and the like. In addition, the wiring layers 112a and 112b may include pad patterns for connection vias, pad patterns for electrical connection structures, and the like. Thicknesses of the wiring layers 112a and 112b of the core member 110 may be greater than those of the redistribution layers 142 of the connection member 140. The reason is that the core member 110 may have a thickness similar to that of the semiconductor chip 120, but the connection member 140 is preferred to be thinner to reduce the overall thickness of the package. Moreover, processes of the core member 110 and the connection member 140 are different from each other.

The connection vias 113 may penetrate through the insulating layer 111 and electrically connect the first wiring layer 112a and the second wiring layer 112b to each other. A material of each of the connection vias 113 may be the conductive material described above. Each of the connection vias 113 may be completely filled with the conductive material, or the conductive material may be formed along a wall of each of connection via holes. Each of the connection vias 113 may be a through-connection-via completely penetrating through the insulating layer 111, and may have a cylindrical shape or a hourglass shape, but is not limited thereto.

The semiconductor chip 120 may be an integrated circuit (IC) provided in an amount of several hundred to several million or more elements integrated in a single chip. The semiconductor chip 120 may be formed on the basis of an active wafer. In this case, a base material of a body 121 of the semiconductor chip 120 may be silicon (Si) , germanium (Ge) , gallium arsenide (GaAs), or the like. Various circuits may be formed on the body 121. The connection pads 122 may electrically connect the semiconductor chip 120 to other components. A material of each of the connection pads 122 may be a conductive material such as aluminum (Al), or the like. The active surface of the semiconductor chip 120 refers to a surface of the semiconductor chip 120 on which the connection pads 122 are disposed, and the inactive surface of the semiconductor chip 120 refers to a surface of the semiconductor chip 120 opposing the active surface. A passivation layer 123 covering at least portions of the connection pads 122 may be formed on the body 121, if necessary. The passivation layer 123 may be an oxide layer, a nitride layer, or the like, or be a double layer of an oxide layer and a nitride layer. An insulating layer (not illustrated), and the like, may also be further disposed in other required positions. The semiconductor chip 120 may be a memory chip such as a volatile memory (for example, a DRAM), a non-volatile memory (for example, a ROM), a flash memory, or the like; an application processor chip such as a central processor (for example, a CPU), a graphics processor (for example, a GPU), a digital signal processor, a cryptographic processor, a microprocessor, a microcontroller, or the like; and a logic chip such as an ADC converter, an ASIC, or the like, but is not necessarily limited thereto.

The passive components 125A and 125B may be various passive components such as capacitors, inductors, beads, and the like. The passive components 125A and 125B may be the same kind of passive components or may be different kinds of passive components. The passive components 125A and 125B may also be electrically connected to each other through the redistribution layers 142 of the connection member 140, and may also be electrically connected to the connection pads 122 of the semiconductor chip 120 through the redistribution layers 142. Meanwhile, the number of electronic components such as the semiconductor chips 120 or the passive components 125A and 125B may be more than that illustrated in the drawings or be less than that illustrated in the drawings depending on a design.

The first encapsulant 130 may protect the semiconductor chip 120 and/or the passive components 125A and 125B. An encapsulation form of the first encapsulant 130 is not particularly limited, but may be a form in which the first encapsulant 130 surrounds at least portions of each of the core member 110, the semiconductor chip 120, and/or the passive components 125A and 125B. The first encapsulant 130 may also fill at least a portion of the through-hole 110H. A certain material of the first encapsulant 130 is not particularly limited, but may be, for example, an insulating material. For example, the first encapsulant 130 may include an ABF including an insulating resin and an inorganic filler. However, a photoimagable encapsulant (PIE) or a material including a glass fiber such as prepreg may be used as a material of the first encapsulant 130, if necessary.

The connection member 140 may include the redistribution layers 142 that may redistribute the connection pads 122 of the semiconductor chip 120. Several tens to several millions of connection pads 122 having various functions may be redistributed by the connection member 140, and may be physically or electrically externally connected through the electrical connection structures 190 depending on the functions.

In addition, a plurality of passive components 125A and 125B and the electronic components 160 may be electrically connected to the connection pads 122 of the semiconductor chip 120 through the redistribution layers 142 depending on functions, and may be physically and/or electrically externally connected through the electrical connection structures 190 depending on the functions. The connection member 140 may include one or more insulating layers 141, one or more redistribution layers 142 disposed on the respective insulating layers 141, and redistribution vias 143 penetrating through the respective insulating layers 141 and electrically connecting the redistribution layers 142, the first wiring layer 112a, the connection pads 122, and the passive components 125A and 125B formed on different layers to each other. Depending on a design, the connection member 140 may include insulating layers, redistribution layers, and redistribution vias of which the numbers are more than those illustrated in the drawings.

A material of each of the insulating layers 141 may be an insulating material. In this case, a photosensitive insulating material such as a PID resin may also be used as the insulating material. This case may be advantageous in forming fine patterns. In some cases, an ABF or a solder resist (SR) may be used as a material of the outermost insulating layer 141.

The redistribution layers 142 may include a conductive material such as copper (Cu), aluminum (Al), silver (Ag), tin (Sn), gold (Au), nickel (Ni), lead (Pb), titanium (Ti), or alloys thereof. The redistribution layers 142 may perform various functions depending on designs of corresponding layers. For example, the redistribution layers 142 may include ground (GND) patterns, power (PWR) patterns, signal (S) patterns, and the like. Here, the signal (S) patterns may include various signals except for the ground (GND) patterns, the power (PWR) patterns, and the like, such as data signals, and the like. In addition, the redistribution layers 142 may include pad patterns for connection vias, pad patterns for electrical connection structures, pad patterns for electronic components, and the like.

The redistribution vias 143 may electrically connect the redistribution layers 142, the first wiring layers 112a, the connection pads 122, the passive components 125A and 125B, and the like, formed on different layers to each other. A material of each of the redistribution vias 143 may be the conductive material described above. Each of the redistribution vias 143 may be completely filled with the conductive material, or the conductive material may also be formed along a wall of each of redistribution via holes. In addition, each of the redistribution vias 143 may have any shape known in the related art such as a tapered shape.

The second encapsulant 150 may protect the electronic components 160. An encapsulation form of the second encapsulant 150 is not particularly limited, but may be a form in which the second encapsulant 150 surrounds at least portions of the electronic components 160. The second encapsulant 150 may include the core layer 151 having the cavities 151H1 and 151H2 in which the electronic components 160 are disposed and the resin layer 152 covering at least portions of the core layer 151 and the electronic components 160 and filling at least portions of the cavities 151H1 and 151H2. A material of the core layer 151 may be prepreg, and a material of the resin layer 152 may be an ABF or a PIE. However, the materials of the core layer 151 and the resin layer 152 are not limited thereto, and both of the materials of the core layer 151 and the resin layer 152 may be prepreg. However, it may be advantageous in terms of maintenance of rigidity and securing of a filling property to use the prepreg as the material of the core layer 151 and use the ABF or the PIE as the material of the resin layer 152. That is, a material having an elastic modulus greater than that of the resin layer 152 may be used as the material of the core layer 151. The lower surface of the second encapsulant 150 may be spaced apart from the upper surface of the connection member 140 by the predetermined interval h. The reason is that the electronic components 160 are encapsulated with the second encapsulant 150 before the electronic components 160 are mounted on the connection member 140 as seen from processes to be described below. A yield problem in manufacturing the fan-out component package 100A may be solved by spacing the lower surface of the second encapsulant 150 apart from the upper surface of the connection member 140.

The electronic components 160 may be various active components and/or passive components. That is, the electronic components 160 maybe integrated circuits (IC) or may be passive components such as capacitors or inductors. The electronic components 160 may be the same kind of components or may be different kinds of components. The respective electronic components 160 maybe mounted on the connection member 140 and be electrically connected to the redistribution layers 142, through the low melting point metals 165. The low melting point metal 165 refers to a metal such as tin (Sn) having a melting point lower than that of copper (Cu), and may be, for example, a solder bump, or the like. At least one of the electronic components 160 may be disposed in a region in the active region of the semiconductor chip 120 when viewed in a direction perpendicular to the active surface of the semiconductor chip 120. That is, the electronic components 160 may be mounted in most of the regions on the connection member 140. In addition, since the electronic components 160 are directly mounted on the connection member 140, when a plurality of electronic components 160 are mounted, an interval between the electronic components 160, for example, an interval between the passive components may be significantly reduced, such that a mounting density may be improved. Meanwhile, the underfill resin 170 may be disposed between the connection member 140 and the second encapsulant 150 to serve to bond the connection member 140 and the second encapsulant 150 to each other, and may bury the low melting point metals 165 to serve to more effectively mount and fix the electronic components 160 on and to the connection member 140.

The plurality of openings 131 exposing at least portions of the second wiring layer 112b of the core member 110 may be formed in the lower surface of the first encapsulant 130, and the underbump metals 180 electrically connected to the exposed second wiring layer 112b may be disposed in the openings 131, respectively. In addition, the plurality of electronic connection structures 190 electrically connected to the exposed second wiring layer 112b through the underbump metals 180 depending on functions may be disposed beneath the first encapsulant 130. In the fan-out component package 100A according to the exemplary embodiment, the electronic connection structures 190 are disposed in only a fan-out region as described above, and a separate backside wiring layer may thus not be required. Therefore, a thickness of the fan-out component package 100A may be more effectively reduced. Meanwhile, a surface treatment layer (not illustrated) may be formed on the exposed second wiring layer 112b. The surface treatment layer (not illustrated) may include Ni—Au. The underbump metals 180 may be formed by any known metallization method.

The electrical connection structures 190 may physically and/or electrically externally connect the fan-out component package 100A, and the fan-out component package 100A according to the exemplary embodiment may be mounted on the mainboard of the electronic device through the electrical connection structures 190. Each of the electrical connection structures 190 may be formed of a low melting point metal, for example, a solder such as an alloy including tin (Sn), more specifically, a tin (Sn)-aluminum (Al)-copper (Cu) alloy, or the like. However, this is only an example, and a material of each of the electrical connection structures 190 is not particularly limited thereto. Each of the electrical connection structures 190 may be a land, a ball, a pin, or the like. The electrical connection structures 190 may be formed as a multilayer or single layer structure. When the electrical connection structures 190 are formed as a multilayer structure, the electrical connection structures 190 may include a copper (Cu) pillar and a solder. When the electrical connection structures 190 are formed as a single layer structure, the electrical connection structures 190 may include a tin-silver solder or copper (Cu). However, this is only an example, and the electrical connection structures 190 are not limited thereto. The number, an interval, a disposition form, and the like, of electrical connection structures 190 are not particularly limited, but may be sufficiently modified depending on design particulars by those skilled in the art. For example, the electrical connection structures 190 may be provided in an amount of several tens to several millions, or may be provided in an amount of several tens to several millions or more or several tens to several millions or less.

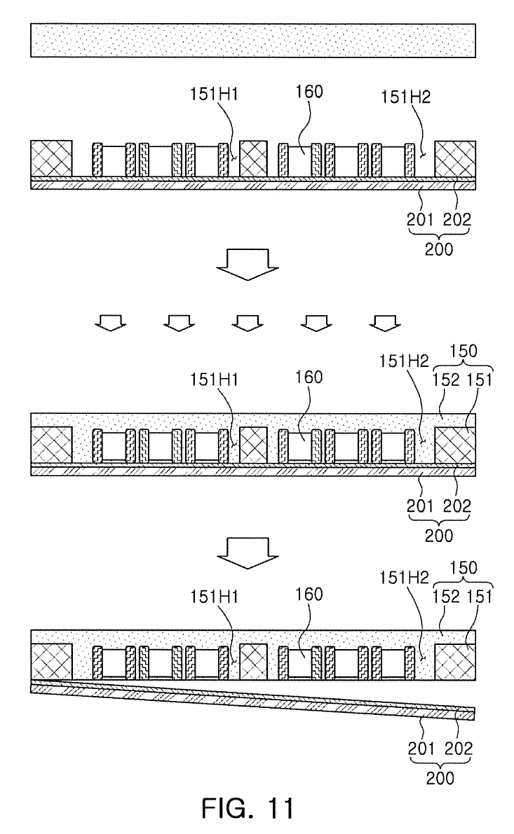

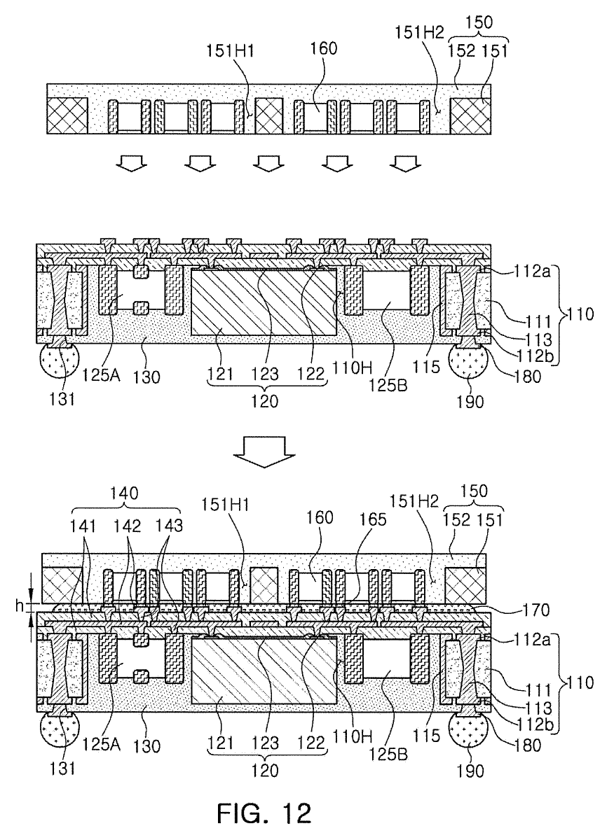

FIGS. 11 and 12 are schematic views illustrating processes of manufacturing the fan-out component package of FIG. 9.

Referring to FIG. 11, the core layer 151 in which the cavities 151H1 and 151H2 are drilled in advance may be disposed on a carrier substrate 200, and one or more electronic components 160 may be disposed on the carrier substrate 200 in the cavities 151H1 and 151H2. The carrier substrate 200 may include a support layer 201 and an adhesive layer 202, and the core layer 151 and the electronic components 160 may be attached to the adhesive layer 202. Then, the resin layer 152 may be compressed and hardened on the adhesive layer 202. The second encapsulant 150 may be formed by these processes. However, the core layer 151 may be omitted, and the electronic components 160 may be simply attached to the adhesive layer 202 and be then encapsulated with only the resin layer 152. After the resin layer is hardened, the carrier substrate 200 may be separated and removed.

Referring to FIG. 12, the semiconductor chip 120 and the passive components 125A and 125B may be packaged in a fan-out package form. The packaging structure may be manufactured by attaching the core member 110 having the through-hole 110H, or the like, to the adhesive layer using the carrier substrate having the adhesive layer as described above, attaching the semiconductor chip 120 and the passive components 125A and 125B to the through-hole 110H, encapsulating the semiconductor chip 120 and the passive components 125A and 125B with the first encapsulant 130, and then forming the connection member 140 by a semiconductor process. The electronic components 160 encapsulated with the second encapsulant 150 may be mounted on the connection member 140 of the manufactured package structure. The electronic components 160 may be mounted using the low melting point metals 165. The fan-out component package 100A according to the exemplary embodiment may be manufactured through a series of processes.

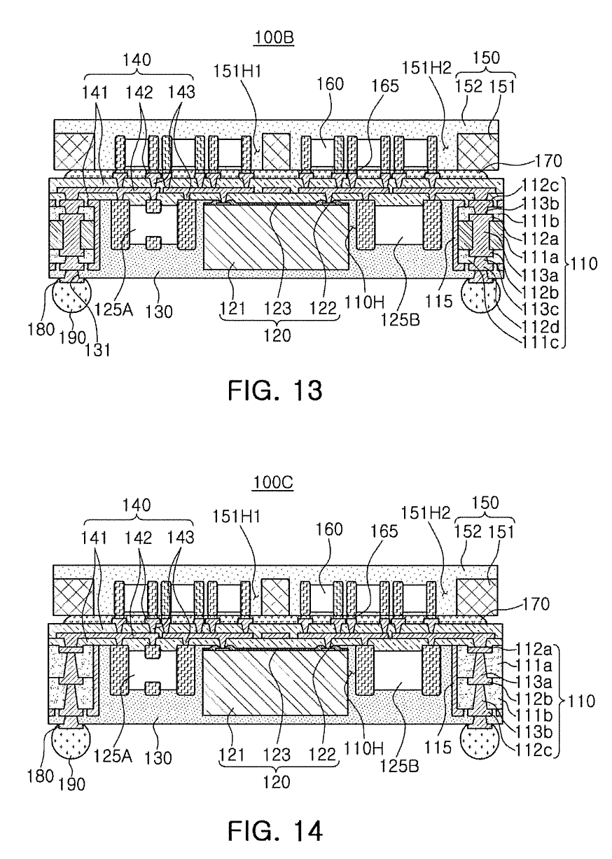

FIG. 13 is a schematic cross-sectional view illustrating another example of a fan-out component package.

Referring to FIG. 13, in a fan-out component package 100B according to another exemplary embodiment in the present disclosure, a core member 110 may include a larger number of wiring layers 112a, 112b, 112c, and 112d. In more detail, the core member 110 may include a first insulating layer 111a, a first wiring layer 112a and a second wiring layer 112b disposed on upper and lower surfaces of the first insulating layer 111a, respectively, a second insulating layer 111b disposed on the upper surface of the first insulating layer 111a and covering the first wiring layer 112a, a third wiring layer 112c disposed on an upper surface of the second insulating layer 111b, a third insulating layer 111c disposed on the lower surface of the first insulating layer 111a and covering the second wiring layer 112b, and a fourth wiring layer 112d disposed on a lower surface of the third insulating layer 111c. The first to fourth wiring layers 112a, 112b, 112c, and 112d may be electrically connected to connection pads 122, passive components 125A and 1258, electronic components 160, and the like. Since the core member 110 may include the larger number of wiring layers 112a, 112b, 112c, and 112d, a connection member 140 may further be simplified. Therefore, a decrease in a yield depending on a defect occurring in a process of forming the connection member 140 may be suppressed. Meanwhile, the first to fourth wiring layers 112a, 112b, 112c, and 112d may be electrically connected to each other through first to third connection vias 113a, 113b, and 113c each penetrating through the first to third insulating layers 111a, 111b, and 111c.

The first insulating layer 111a may have a thickness greater than those of the second insulating layer 111b and the third insulating layer 111c. The first insulating layer 111a may be relatively thick in order to maintain rigidity, and the second insulating layer 111b and the third insulating layer 111c may be introduced in order to form a larger number of wiring layers 112c and 112d. The first insulating layer 111a may include an insulating material different from those of the second insulating layer 111b and the third insulating layer 111c. For example, the first insulating layer 111a may be, for example, prepreg including a core material, a filler, and an insulating resin, and the second insulating layer 111b and the third insulating layer 111c may be an ABF or a PID film including a filler and an insulating resin. However, the materials of the first insulating layer 111a and the second and third insulating layers 111b and 111c are not limited thereto. Similarly, the first connection via 113a penetrating through the first insulating layer 111a may have a diameter greater than those of the second and third connection vias 113b and 113c each penetrating through the second and third insulating layers 111b and 111c.

The first wiring layer 112a and the second wiring layer 112b of the core member 110 may be disposed on a level between an active surface and an inactive surface of the semiconductor chip 120. Since the core member 110 may be formed at a thickness corresponding to that of the semiconductor chip 120, the first wiring layer 112a and the second wiring layer 112b formed in the core member 110 may be disposed on the level between the active surface and the inactive surface of the semiconductor chip 120. Thicknesses of the wiring layers 112a, 112b, 112c, and 112d of the core member 110 maybe greater than that of the redistribution layer 142 of the connection member 140. A description of other configurations overlaps that described above, and is thus omitted.

FIG. 14 is a schematic cross-sectional view illustrating another example of a fan-out component package.

Referring to FIG. 14, in a fan-out component package 1000 according to another exemplary embodiment in the present disclosure, a core member 110 may include a larger number of wiring layers 112a, 112b, and 112c. In more detail, the core member 110 may include a first insulating layer 111a in contact with a connection member 140, a first wiring layer 112a in contact with the connection member 140 and embedded in the first insulating layer 111a, a second wiring layer 112b disposed on a lower surface of the first insulating layer 111a opposing an upper surface of the first insulating layer 111a in which the first wiring layer 112a is embedded, a second insulating layer 111b disposed on the lower surface of the first insulating layer 111a and covering the second wiring layer 112b, and a third wiring layer 112c disposed on a lower surface of the second insulating layer 111b. The first to third wiring layers 112a, 112b, and 112c may be electrically connected to connection pads 122, passive components 125A and 125B, electronic components 160, and the like. The first and second wiring layers 112a and 112b and the second and third wiring layers 112b and 112c may be electrically connected to each other through first and second connection vias 113a and 113b penetrating through the first and second insulating layers 111a and 111b, respectively.

An upper surface of the first wiring layer 112a of the core member 110 may be disposed on a level below an upper surface of the connection pad 122 of a semiconductor chip 120. In addition, a distance between a redistribution layer 142 of the connection member 140 and the first wiring layer 112a of the core member 110 may be greater than that between the redistribution layer 142 of the connection member 140 and the connection pad 122 of the semiconductor chip 120. The reason is that the first wiring layer 112a may be recessed into the first insulating layer 111a. As described above, when the first wiring layer 112a is recessed in the first insulating layer 111a, such that the upper surface of the first insulating layer 111a and the upper surface of the first wiring layer 112a have a step therebetween, a phenomenon in which a material of a first encapsulant 130 bleeds to pollute the first wiring layer 112a may be prevented. The second wiring layer 112b of the core member 110 may be disposed on a level between an active surface and an inactive surface of the semiconductor chip 120. Thicknesses of the wiring layers 112a, 112b, and 112c of the core member 110 may be greater than those of the redistribution layers 142 of the connection member 140. A description of other configurations overlaps that described above, and is thus omitted.

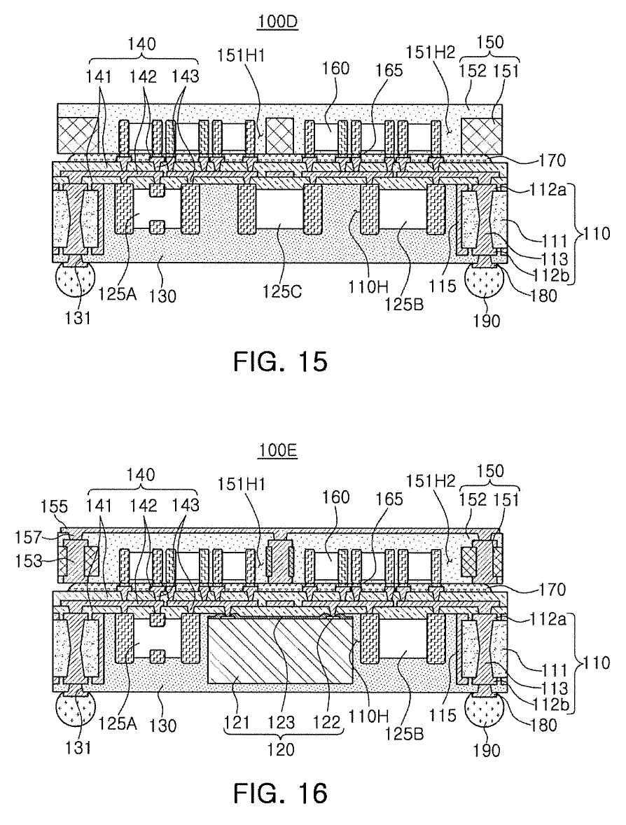

FIG. 15 is a schematic cross-sectional view illustrating another example of a fan-out component package.

Referring to FIG. 15, in a fan-out component package 100D according to another exemplary embodiment in the present disclosure, a semiconductor chip 120 may be omitted, and a passive component 125C may further be disposed at a lower portion of the fan-out component package 100C. In this case, all electronic components 160 may also be passive components. That is, the fan-out component package 100D may include only passive components 125A, 125B, 125C, and 160. A description of other configurations overlaps that described above, and is thus omitted.

FIG. 16 is a schematic cross-sectional view illustrating another example of a fan-out component package.

Referring to FIG. 16, in a fan-out component package 100E according to another exemplary embodiment in the present disclosure, blocking vias 153 maybe formed in a core layer 151, and a blocking layer 155 may be formed on a resin layer 152. The blocking layer 155 may be connected to the blocking vias 153 through sub-blocking vias 157, or the like. A heat dissipation effect and an electromagnetic wave blocking effect of electronic components 160 may be achieved through the blocking vias 153, the blocking layer 155, and the sub-blocking vias 157. All of the blocking vias 153, the blocking layer 155, and the sub-blocking vias 157 may be formed of a conductive material, and may be foamed by plating. Meanwhile, a blocking member (not illustrated) having a form of a stack via formed of a conductive material may be disposed outside a connection member 140, and an electromagnetic wave blocking effect of a redistribution layer 142 may also be achieved through the blocking member (not illustrated). The blocking member (not illustrated) maybe connected to the blocking vias 153, or the like, described above, if necessary. The blocking member (not illustrated) may also be connected to a metal layer 115, if necessary. That is, all the heat dissipation and blocking members may be connected to each other, and may be connected to a ground in the redistribution layer 142, if necessary. A description of other configurations overlaps that described above, and is thus omitted.

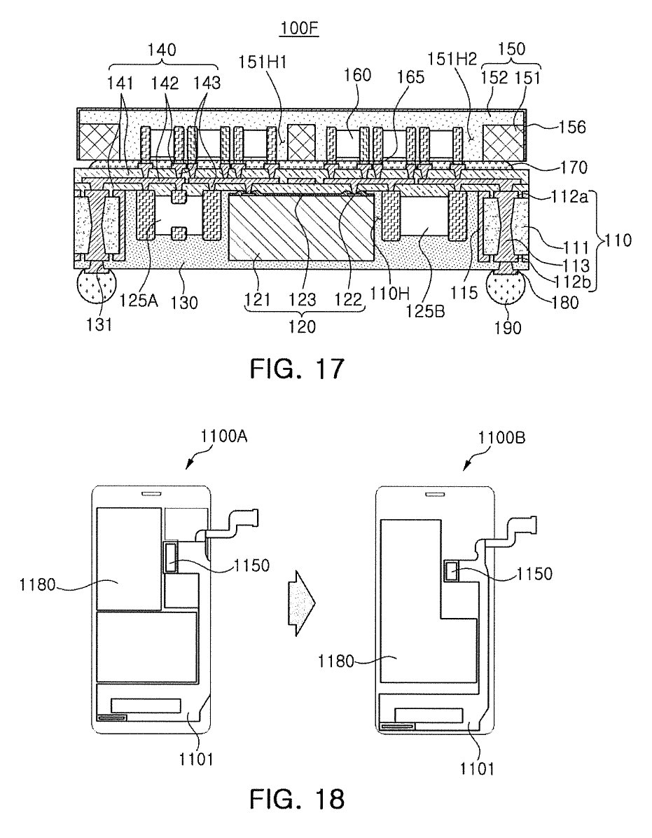

FIG. 17 is a schematic cross-sectional view illustrating another example of a fan-out component package.

Referring to FIG. 17, in a fan-out component package 100F according to another exemplary embodiment in the present disclosure, a blocking layer 156 may be formed on an outer surface of a second encapsulant 150. That is, outer side surfaces of a core layer 151 and an upper surface and outer side surfaces of a resin layer 152 may be covered with the blocking layer 156. A heat dissipation effect and an electromagnetic wave blocking effect of electronic components 160 may be achieved through the blocking layer 156. The blocking layer 156 may be formed of a conductive material, and may be formed by sputtering, or the like. Meanwhile, a blocking member (not illustrated) having a form of a stack via formed of a conductive material may be disposed outside a connection member 140, and an electromagnetic wave blocking effect of a redistribution layer 142 may also be achieved through the blocking member (not illustrated) . The blocking member (not illustrated) may be connected to the blocking layer 156, or the like, described above, if necessary. The blocking member (not illustrated) may also be connected to a metal layer 115, if necessary. That is, all the heat dissipation and blocking members may be connected to each other, and may be connected to a ground in the redistribution layer 142, if necessary. A description of other configurations overlaps that described above, and is thus omitted.

FIG. 18 is schematic plan views illustrating one effect in a case in which a fan-out component package according to the present disclosure is used on a main board of an electronic device.

Referring to FIG. 18, recently, in accordance with an increase in sizes of displays for mobile apparatuses 1100A and 1100B, the necessity to increase capacity of batteries has increased. In accordance with the increase in the capacity of the battery, an area occupied by the battery 1180 in the mobile apparatus has increased, and it has been thus required to reduce a size of a mainboard 1101. Therefore, a mounting area of components has reduced, such that an area that may be occupied by a module 1150 including an integrated circuit such as a power management integrated circuit (PMIC) and a passive component such as a capacitor has continuously reduced. However, when the fan-out component package 100A, 100B, 100C, 100D, 100E, or 100F according to the present disclosure is used instead of the module, a size of the module 1150 may be significantly reduced, and the reduced area as described above may thus be effectively used.

As set forth above, according to an exemplary embodiment in the present disclosure, a fan-out component package of which a mounting density may be increased in a mainboard in an electronic device, a thickness may be significantly decreased in spite of the increase in the mounting density, and electrical characteristics may be improved due to a reduction in a signal distance may be provided.

While exemplary embodiments have been shown and described above, it will be apparent to those skilled in the art that modifications and variations could be made without departing from the scope of the present invention as defined by the appended claims.

1. A fan-out component package comprising:
a core member having a through-hole and including a plurality of wiring layers and one or more connection vias electrically connecting the plurality of wiring layers to each other;
one or more first electronic components disposed in the through-hole;
a first encapsulant covering at least portions of each of the core member and the first electronic components and filling at least a portion of the through-hole;
a connection member disposed on the core member and the first electronic components and including one or more redistribution layers electrically connected to the wiring layers and the first electronic components;
one or more second electronic components disposed on the connection member and electrically connected to the redistribution layers; and
a second encapsulant disposed on the connection member and encapsulating the second electronic components,
wherein an upper surface of the connection member and a lower surface of the second encapsulant are spaced apart from each other by a predetermined interval.

2. The fan-out component package of claim 1, wherein the second electronic components are connected to the redistribution layers by a low melting point metal.

3. The fan-out component package of claim 2, further comprising an underfill resin disposed between the upper surface of the connection member and the lower surface of the second encapsulant and burying the low melting point metal.

4. The fan-out component package of claim 1, wherein at least one of the first electronic components is a semiconductor chip having an active surface having connection pads disposed thereon and an inactive surface opposing the active surface,
the semiconductor chip is disposed so that the active surface faces the connection member, and
the redistribution layers are electrically connected to the connection pads.

5. The fan-out component package of claim 4, wherein another of the first electronic components is a first passive component,
at least one of the second electronic components is a second passive component, and
the first passive component has a thickness greater than that of the second passive component.

6. The fan-out component package of claim 1, wherein the first and second electronic components are a plurality of passive components, respectively.

7. The fan-out component package of claim 1, wherein the second encapsulant includes a core layer and a resin layer,
the core layer has cavities in which the second electronic components are disposed, and
the resin layer covers at least portions of each of the core layer and the second electronic components and fills at least portions of the cavities.

8. The fan-out component package of claim 7, wherein the core layer has an elastic modulus greater than that of the resin layer.

9. The fan-out component package of claim 7, further comprising:
blocking vias penetrating through the core layer; and
a blocking layer disposed on the second encapsulant and connected to the blocking vias.

10. The fan-out component package of claim 1, further comprising a blocking layer covering an outer surface of the second encapsulant.

11. The fan-out component package of claim 1, further comprising:
a plurality of openings formed in a lower surface of the
first encapsulant and exposing at least portions of a wiring layer disposed at a lowermost portion among the wiring layers; a plurality of underbump metals disposed in the openings, respectively, and electrically connected to the exposed wiring layer; and
a plurality of electrical connection structures disposed beneath the first encapsulant and electrically connected to the exposed wiring layer through the underbump metals,
wherein the electrical connection structures are disposed in only a fan-out region.

12. The fan-out component package of claim 11, further comprising a metal layer disposed on walls of the through-hole.

13. The fan-out component package of claim 1, wherein the core member includes a first insulating layer, a first wiring layer disposed on an upper surface of the first insulating layer, a second wiring layer disposed on a lower surface of the first insulating layer, and first connection vias penetrating through the first insulating layer and connecting the first and second wiring layers to each other.

14. The fan-out component package of claim 13, wherein the core member further includes a second insulating layer disposed on the upper surface of the first insulating layer and covering the first wiring layer, a third wiring layer disposed on the second insulating layer, a third insulating layer disposed on the lower surface of the first insulating layer and covering the second wiring layer, a fourth wiring layer disposed on the third insulating layer, second connection vias penetrating through the second insulating layer and connecting the first and third wiring layers to each other, and third connection vias penetrating through the third insulating layer and connecting the second and fourth wiring layers to each other.

15. The fan-out component package of claim 1, wherein the core member includes a first insulating layer in contact with the connection member, a first wiring layer in contact with the connection member and embedded in the first insulating layer, a second wiring layer disposed on a lower surface of the first insulating layer opposing an upper surface of the first insulating layer in which the first wiring layer is embedded, a second insulating layer disposed on the lower surface of the first insulating layer and covering the second wiring layer, a third wiring layer disposed on a lower surface of the second insulating layer, first connection vias penetrating through the first insulating layer and connecting the first and second wiring layers to each other, and second connection vias penetrating through the second insulating layer and connecting the second and third wiring layers.

16. A fan-out component package comprising:
a core member having a through-hole and including a plurality of wiring layers and one or more connection vias electrically connecting the plurality of wiring layers to each other;
a semiconductor chip disposed in the through-hole and having an active surface having connection pads disposed thereon and an inactive surface opposing the active surface;
a first encapsulant covering at least portions of each of the core member and the inactive surface of the semiconductor chip and filling at least a portion of the through-hole;
a connection member disposed on the core member and the active surface of the semiconductor chip and including one or more redistribution layers electrically connected to the wiring layers and the connection pads;
a plurality of passive components disposed on the connection member and electrically connected to the redistribution layers; and
a second encapsulant disposed on the connection member and encapsulating the plurality of passive components,
wherein at least one of the plurality of passive components is disposed in the active surface of the semiconductor chip when viewed in a direction perpendicular to the active surface of the semiconductor chip.

17. A fan-out component package comprising:
a connection member comprising a redistribution layer and having a first surface and a second surface opposing the first surface;
a first electronic component disposed in a through-hole of a core member, the core member comprising a wiring layer electrically connected to the first electronic component, the first electronic and the core member being disposed on a first surface of the connection member such that the first electronic component, the redistribution layer and the wiring layer are electrically connected to each other;
a first encapsulant filling at least a portion of the through-hole and covering at least portions of the first electronic component and the core member;
a second electronic component disposed on the second surface of the connection member and electrically connected to the redistribution layer; and
a second encapsulant disposed on, and spaced apart from the second surface of the connection member by a predetermined distance, the second encapsulant encapsulating the second electronic component.

18. The fan-out component package of claim 17, wherein the first electronic component comprises a plurality of electronic components including at least a semiconductor chip and a passive component, the semiconductor chip having connection pads facing the first surface of the connection member and electrically connected to the wiring layer and the redistribution layer.

19. The fan-out component package of claim 17, wherein the connection member comprises a plurality of redistribution layers electrically connected to each other by redistribution vias.

20. The fan-out component package of claim 17, wherein a space between the second encapsulant and the second surface of the connection member is filled by an underfill resin, and the second electronic component is electrically connected to the redistribution layer by a low melting point metal penetrating through the underfill resin.

21. A fan-out component package comprising:
a connection member comprising one or more redistribution layers and having a first side and a second side opposing the first side;
a frame disposed on the first side of the connection member and having a through-hole;
a semiconductor chip disposed on the first side of the connection member and disposed in the through-hole, and having connection pads disposed on a surface of the semiconductor chip facing the first side of the connection member and electrically connected to the one or more redistribution layers;
an encapsulant disposed on the first side of the connection member, filling at least a portion of the through-hole, and covering at least a portion of the frame and at least a portion of the semiconductor chip;
one or more passive components disposed on the second side of the connection member and electrically connected to the one or more redistribution layers; and
a molding compound disposed on the second side of the connection member, and covering at least a portion of the one or more passive components,
wherein the frame includes a first insulating layer disposed on the first side of the connection member, a first wiring layer in contact with the first side of the connection member and embedded in the first insulating layer, a second wiring layer disposed on a second surface of the first insulating layer opposing a first surface of the first insulating layer in which the first wiring layer is embedded, and a first connection via penetrating through the first insulating layer and electrically connecting the first and second wiring layers to each other, and
the first and second wiring layers are electrically connected to the connection pads through the one or more redistribution layers.

22. The fan-out component package of claim 21, wherein the frame further includes a second insulating layer disposed on the second surface of the first insulating layer and covering at least a portion of the second wiring layer, a third wiring layer disposed on a second surface of the second insulating layer opposing a first surface of the second insulating layer in which the second wiring layer is embedded, and a second connection via penetrating through the second insulating layer and electrically connecting the second and third wiring layers to each other, and
the third wiring layer is electrically connected to the connection pads through the one or more redistribution layers.
